(19) United States
(12) Patent Application Publication
(10) Pub. No.: US 2024/0274635 A1
(43) Pub. Date: Aug. 15, 2024

(54) OPTICAL SENSOR DEVICE

(71) Applicant: Vanguard International Semiconductor Corporation, Hsinchu (TW)

(72) Inventors: Shih-Hao LIU, Taoyuan City (TW); Yu-Che TSAI, Hsinchu City (TW); Jui-Chun CHANG, Hsinchu City (TW); Wu-Hsi LU, New Taipei City (TW); Ming-Cheng LO, New Taipei City (TW)

(73) Assignee: Vanguard International Semiconductor Corporation, Hsinchu (TW)

(21) Appl. No.: 18/168,321

(22) Filed: Feb. 13, 2023

(51) Int. Cl. H01L 27/146

(52) U.S. Cl. CPC H01L 27/1463

(57) ABSTRACT

An optical sensor device is provided. The optical sensor device includes a semiconductor substrate, an isolation feature, a first doped region, a second doped region, and a third doped region. The semiconductor substrate of a first conductivity type includes a sensing region surrounded by an isolation region. The first doped region of a second conductivity type is located in the sensing region. The second doped region of the second conductivity type is located in the sensing region and above the first doped region. The third doped region of the first conductivity type is located in the sensing region and on the second doped region. In a cross-sectional view, the first doped region has a first length, the second doped region has a second length, and a first ratio, which is the ratio of the second length to the first length, is greater than 0 and less than 1.

### BACKGROUND OF THE INVENTION

### Field of the Invention

The present invention relates to an optical sensor device, and, in particular, to an optical sensor.

### Description of the Related Art

Optical sensors (such as image sensors) are used to convert optical images (which are focused onto the image sensor) into electrical signals. The image sensor usually includes an array of pixels, wherein each pixel includes a light-detecting element, such as a photodiode. The light-detecting element is configured to generate an electrical signal that corresponds to the intensity of the light that is impinging on (or incident to) the light-detecting element. The electrical signal that is generated can be processed further by a signal-processing circuit to provide information about the optical image being displayed.

The current technology used to manufacture optical sensors (including ambient light sensors (ALS) for receiving visible light and proximity sensors (PS) for receiving infrared light) of the type used in smartphones has been continuously and rapidly developed to improve the battery life of said smartphones. However, the dark current problem in optical sensors still needs to be improved upon further.

### BRIEF SUMMARY OF THE INVENTION

An embodiment of the disclosure provides an optical sensor device. The optical sensor device includes a semiconductor substrate, a first doped region, a second doped region and a third doped region. The semiconductor substrate has a first conductivity type. The semiconductor substrate includes a sensing region and an isolation region surrounding the sensing region. The first doped region is located in the sensing region. The first doped region has a second conductivity type. The second doped region is located in the sensing region and above the first doped region. The second doped region has the second conductivity type. The third doped region is located in the sensing region and on the second doped region. The third doped region has the first conductivity type. In a cross-sectional view, the first doped region has a first length, and the second doped region has a second length. A first ratio, which is the ratio of the second length to the first length, is greater than 0 and less than 1.

### BRIEF DESCRIPTION OF THE DRAWINGS

The present invention can be more fully understood by reading the subsequent detailed description and examples with references made to the accompanying drawings, wherein:

FIG. 1 is a schematic top view of an optical sensor device in accordance with some embodiments of the disclosure;

FIG. 2 is a schematic cross-sectional view along the line A-A′ of the optical sensor device of FIG. 1 in accordance with some embodiments of the disclosure;

FIG. 3 is a schematic cross-sectional view along the line B-B′ of the optical sensor device of FIG. 1 in accordance with some embodiments of the disclosure; and

FIG. 4 is a schematic cross-sectional view along the line C-C′ of the optical sensor device in FIG. 1 in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

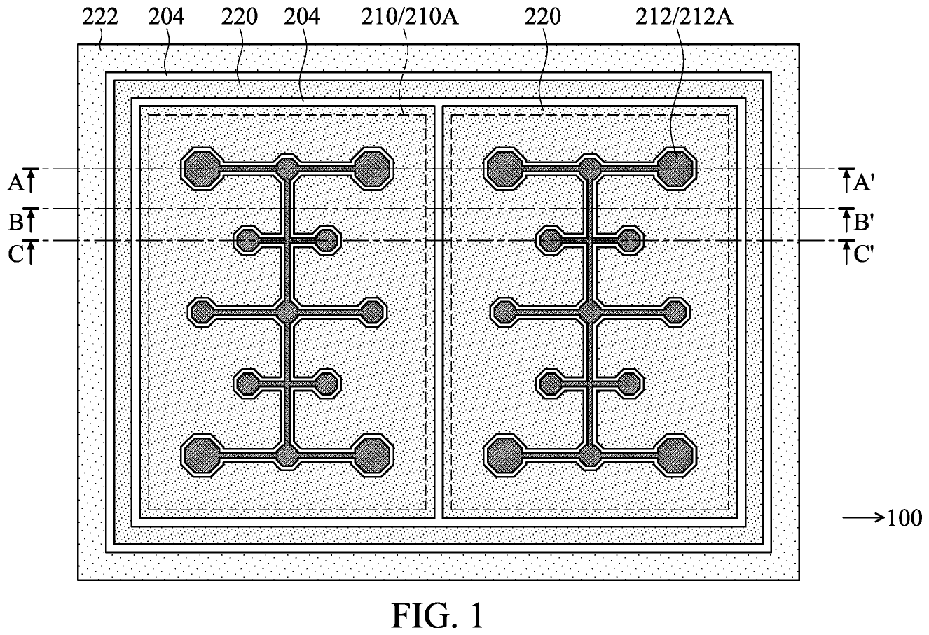

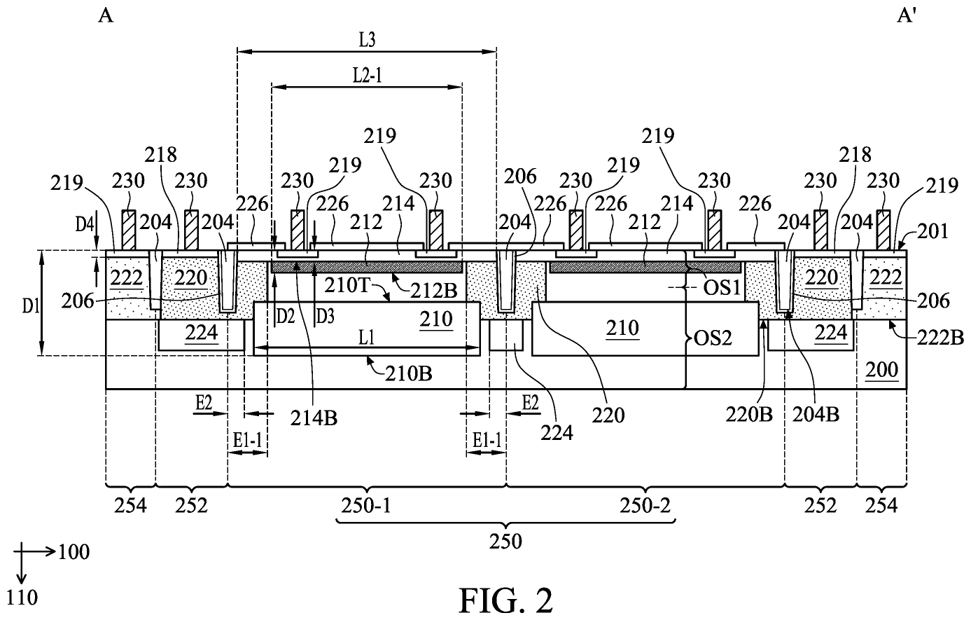

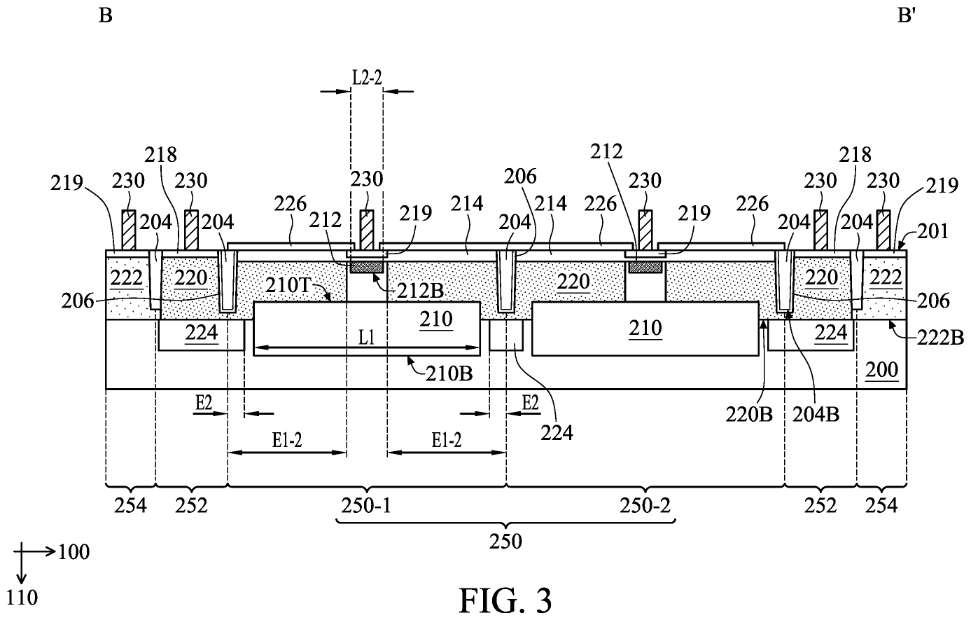

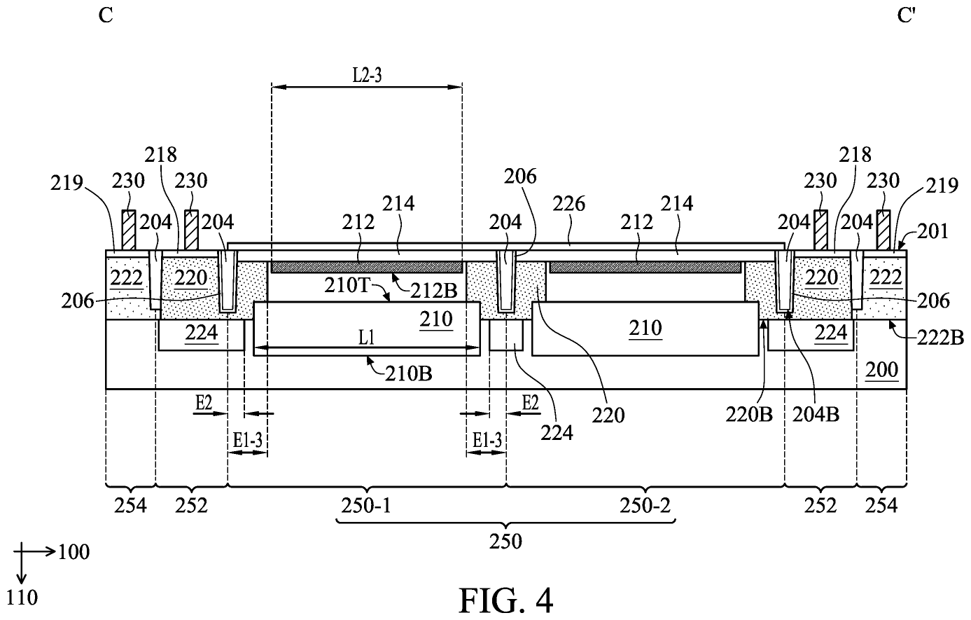

FIG. 1 is a schematic top view of an optical sensor device 500 in accordance with some embodiments of the disclosure. FIGS. 2, 3, and 4 are respectively schematic cross-sectional views along the lines A-A′, B-B′, and C-C′ substantially parallel to the direction 100 of the optical sensor device 500 of FIG. 1 in accordance with some embodiments of the disclosure. FIG. 1 only shows some features for illustration, and the remaining features may be shown in the schematic cross-sectional views of FIGS. 2, 3, and 4. In some embodiments, the optical sensor device 500 includes a semiconductor substrate 200, an isolation feature 204, a first doped region 210, a second doped region 212, a third doped region 214, a first well region 220 and a second well region 222.

In some embodiments, the semiconductor substrate 200 includes an elementary semiconductor, such as silicon (Si), germanium (Ge), etc.; a compound semiconductor, such as gallium nitride (GaN), silicon carbide (SiC), gallium arsenide (GaAs), gallium phosphide (GaP), indium phosphide (InP), indium arsenide (InAs), indium antimonide (InSb), etc.; an alloy semiconductor, such as SiGe alloy, GaAsP alloy, AlInAs alloy, AlGaAs alloy, GaInAs alloy, GaInP alloy, GaInAsP alloy, or a combination thereof. In addition, the semiconductor substrate 200 may also include a silicon-on-insulator (SOI). In some embodiments, the conductivity type of the semiconductor substrate 200 may be P-type or N-type depending on design requirements. In this embodiment, the semiconductor substrate 200 can be doped with dopants to have a first conductivity type, such as P-type. The dopants include, such as boron (B), aluminum (Al), gallium (Ga), indium (In), boron trifluoride ions (BF₃^{'}), or a combination thereof. The doping concentration of the semiconductor substrate 200 is between about 1E14 atoms/cm² and 1E15 atoms/cm². In some embodiments, the semiconductor substrate 200 includes a sensing region 250 (including adjacent sensing regions 250-1 and 250-2), an isolation region 252 surrounding the sensing region 250, and a guard ring region 254 surrounding the isolation region 252.

The optical sensor device 500 has a plurality of isolation features 204 extending from a top surface 201 of the semiconductor substrate 200 into a portion of the semiconductor substrate 200. The isolation features 204 are used to define a sensing region 250, an isolation region 252 and a guard ring region 254. As shown in FIGS. 1-4, the isolation features 204 are located between the sensing region 250 and the isolation region 252, and between the isolation region 252 and the guard ring region 254. In addition, the isolation feature 204 may be disposed between the adjacent sensing regions 250-1 and 250-2. In some embodiments, the isolation features 204 are formed of, for example, silicon oxide (SiO), silicon nitride (SiN), silicon oxynitride (SiON), and/or a combination thereof. In some embodiments, the isolation features 204 are formed using a patterning process followed by a deposition process and a planarization process.

As shown in FIG. 1 to FIG. 4, the first doped regions 210 are located below the top surface 201 of the semiconductor substrate 200 in the sensing regions 250-1 and 250-2, and is located between the isolation feature 204 between the sensing regions 250-1 and 250-2 and the isolation feature 204 between the sensing region 250 and the isolation region 252. The first doped region 210 has a top surface 210T and a bottom surface 210B. In addition, bottom surfaces 204B of the isolation features 204 are located above the bottom surface 210B of the first doped region 210. As shown in the cross-sectional views shown in FIGS. 2-4, the first doped region 210 has the same first length L1 along a direction 100 (the direction substantially parallel to the top surface 201 of the semiconductor substrate 200). In addition, the first doped region 210 has a first depth D1 (i.e., the distance between the bottom surface 210B of the first doped region 210 and the top surface 201 of the semiconductor substrate 200) along a direction 110 (the direction substantially perpendicular to the top surface 201 of the semiconductor substrate 200). The first doped region 210 is not connected to the adjacent isolation features 204. In other words, the first length L1 of the first doped region 210 may be less than the distances (not shown) between adjacent isolation features 204 in the sensing regions 250-1 and 250-2. In some embodiments, the first doped region 210 has a second conductivity type opposite to the first conductivity type. For example, when the semiconductor substrate 200 is, for example, a P-type semiconductor substrate, the first doped region 210 is, for example, an N-type deeply doped region. In some embodiments, the doping concentration of the first doped region 210 is between about 1E15 atoms/cm² and about 1E17 atoms/cm².

The second doped region 212 is located below the top surface 201 of the semiconductor substrate 200 in the sensing regions 250-1 and 250-2, and is located above the first doped region 210. Compared with the first doped region 210, the second doped region 212 is closer to the top surface 201 of the semiconductor substrate 200. As shown in FIG. 2, the second doped region 212 and the first doped region 210 are separated from each other. In other words, the second doped region 212 is not adjacent to the first doped region 210. In addition, there is no interface between the second doped region 212 and the first doped region 210. As shown in the top view of FIG. 1, a top-view area (the vertical projection area) 212A of the second doped region 212 may be less than a top-view area 210A of the first doped region 210. For example, the top-view area 212A may be less than half of the top-view area 210A. In addition, the first doped region 210 has a first projection (having the same shape as that of the top-view area 210A) in a top-view direction (perpendicular to the plane of the paper of FIG. 1 (i.e., the direction perpendicular to the semiconductor substrate 200) and parallel to the direction 110 in FIGS. 2 to 4). The second doped region 212 has a second projection (having the same shape as that of the top-view area 212A) in the top-view direction. In addition, the second projection is completely located within the first projection. Furthermore, the first doped region 210 and the second doped region 212 may have different top view shapes (i.e., the first projection and the second projection may have different shapes). In the cross-sectional views of FIGS. 2 to 4, the second doped region 212 may have different second lengths along the direction 100, for example, second lengths L2-1, L2-2, and L2-3, while the first doped region 210 has the same first length L1. Moreover, the second lengths L2-1, L2-2 and L2-3 may be all less than the first length L1. In some embodiments, a ratio of each of the second lengths L2-1, L2-2 and L2-3 to the first length L1 is greater than 0 and less than 1. In addition, the second doped region 212 has a second depth D2 along the direction 110 (i.e., the distance between the bottom surface 210B of the second doped region 212 and the top surface 201 of the semiconductor substrate 200). The second depth D2 may be less than the first depth D1. In some embodiments, the second doped region 212 has the second conductivity type. For example, when the semiconductor substrate 200 is, for example, a P-type semiconductor substrate, the second doped region 212 is, for example, an N-type lightly doped region. In some embodiments, the doping concentration of the second doped region 212 is between about 1E15 atoms/cm² and about 1E17 atoms/cm².

The third doped regions 214 are located in the sensing regions 250-1 and 250-2 and on the second doped regions 212. As shown in FIG. 2, the third doped regions 214 are adjacent to the top surface 201 of the semiconductor substrate 200. For example, the third doped regions 214 may extend from the top surface 201 of the semiconductor substrate 200 into portion of the semiconductor substrate 200. In addition, the second doped region 212 is adjacent to a bottom surface 214B of the third doped region 214. Furthermore, the third doped region 214 extends to the isolation feature 204 between the sensing regions 250-1 and 250-2 and the isolation feature 204 between the sensing region 250 and the isolation region 252. In the cross-sectional views of FIGS. 2 to 4, the third doped region 214 has a third length L3 along the direction 100 and a third depth D3 (i. e., the distance between the bottom surface 214B of the third doped region 214 and the top surface 201 of the semiconductor substrate 200) along the direction 110. The third length L3 may be greater than the second length L2-1 and less than the first length L1, and the third depth D3 may be less than the second depth D2. In some embodiments, a ratio of the second length L2-1 to the third length L3 is greater than a ratio of the second length L2-1 to the first length L1 and less than 1. In some embodiments, the third doped region 214 has the first conductivity type. For example, when the semiconductor substrate 200 is, for example, a P-type semiconductor substrate, the third doped region 214 is, for example, a P-type lightly doped region. In some embodiments, the doping concentration of the third doped region 214 is between about 1E15 atoms/cm² and about 1E17 atoms/cm².

In some embodiments, a plurality of P-N junctions of different depths may be formed in the sensing region 250 of the semiconductor substrate 200 by configuring the conductivity types, doping concentrations and depths of the semiconductor substrate 200, the first doped region 210, the second doped region 212 and the third doped region 214, such as the P-N junction formed by joining the semiconductor substrate 200 and the first doped region 210, the P-N junction formed by joining the semiconductor substrate 200 and the second doped region 212, and the P-N junction formed by joining the second doped region 212 and the third doped region 214.

Since the semiconductor substrate 200 has different absorption depths for incident light of different wavelengths. For example, compared to the visible light (the wavelength in the range of about 400 to 700 nm), the invisible light with a longer wavelength (the wavelength longer than 700 nm) may be incident into the semiconductor substrate 200 with a deeper penetration depth. Therefore, the depths of multiple P-N junctions can be adjusted by the aforementioned configurations to correspond incident lights (photons) in different wavelength ranges and generate electron-hole pairs in the P-N junctions at different depths, thereby creating the current signal. It should be noted that the depth and quantity of the P-N junctions included in the embodiments of the disclosure can be adjusted according to design requirements of the products, and are not limited to the disclosed embodiments. In some embodiments, the third doped region 214, the second doped region 212, and a portion of the semiconductor substrate 200 between the second doped region 212 and the first doped region 210 form the first optical sensor OS1. In addition, a portion of the semiconductor substrate 200 between the second doped region 212 and the first doped region 210, the first doped region 210 and another portion of the semiconductor substrate 200 below the first doped region 210 form a second optical sensor OS2. For example, the first optical sensor OS1 can be an ambient light sensor (ALS) that receives visible light, and the second optical sensor OS2 can be a proximity sensor (PS) that receives infrared light with a wavelength of about 940 nm. Since the top-view area 212A of the second doped region 212 is less than the top-view area 210A and the second lengths L2-1, L2-2 and L2-3 of the second doped region 212 are less than the first length L1 of the first doped region 210. The light absorption area of the first optical sensor OS1 for receiving the visible light can be reduced while maintaining the light sensitivity of the optical sensor OS1, so that the dark current of the first optical sensor OS1 can be further suppressed.

As shown in FIGS. 2-4, the optical sensor device 500 further includes fourth doped regions 206. The fourth doped regions 206 surround sides (not shown) and the bottom surfaces 204B of the isolation features 204 between the sensing regions 250-1, 250-2 and the isolation region 252 and between the sensing regions 250-1 and 250-2. The fourth doped region 206 is used to further enhance the dark current isolation capability of the isolation feature 204 surrounding the sensing regions 250-1 and 250-2. In some embodiments, the fourth doped region 206 has the second conductivity type. For example, when the semiconductor substrate 200 is, for example, a P-type semiconductor substrate, the fourth doped region 206 is, for example, a P-type doped region. In some embodiments, the doping concentration of the fourth doped region 206 is between about 1E17 atoms/cm² to about 1E18 atoms/cm².

As shown in FIGS. 1-4, the optical sensor device 500 further includes a first well region 220. The first well region 220 is located in the isolation region 252 and portions of the sensing regions 250-1 and 250-2, and surrounds the second doped region 212. In addition, the first well region 220 surrounds the sides (not shown) and bottom surfaces 204B of the isolation feature 204 between the sensing regions 250-1, 250-2 and the isolation region 252 and between the sensing regions 250-1 and 250-2. In addition, the first well region 220 surrounds the fourth doped region 206. In the cross-sectional views of FIGS. 2 to 4, the first well region 220 in the sensing region 250-1 and 250-2 may have different first extended lengths along the direction 100, for example, the first extended lengths E1-1, E1-2 and E1-3. In some embodiments, the first well region 220 partially overlaps the first doped region 210 and does not overlap the second doped region 212 at all. Moreover, a bottom surface 220B of the first well region 220 is located between the top surface 210T and the bottom surface 210B of the first doped region 210. In addition, the bottom surface 204B of the isolation feature 204 is located above the bottom surface 220B of the first well region 220. In some embodiments, the first well region 220 has the first conductivity type. For example, when the semiconductor substrate 200 is, for example, a P-type semiconductor substrate, the first well region 220 is, for example, a P-type well region. Moreover, the doping concentration of the first well region 220 is greater than the doping concentration of the semiconductor substrate 200. Therefore, the first well region 220 located in the isolation region 252 can be used to electrically isolate the sensing region 250 from the external region. The first well region 220 extending to portions of the sensing region 250-1 and 250-2 can be used to suppress the dark current generated in the first optical sensor OS1 for receiving visible light and the second optical sensor OS2 for receiving infrared light with a wavelength of about 940 nm. In some embodiments, the doping concentration of the first well region 220 is between about 1E17 atoms/cm² and about 1E18 atoms/cm².

As shown in FIGS. 1-4, the optical sensor device 500 further includes a second well region 222. The second well region 222 is located in a guard ring area 254. A bottom surface 222B of the second well region 222 is located below the bottom surface 204B of the isolation feature 204 and may level with the bottom surface 220B of the first well region 220.

The second well region 222 is used to prevent external electrical signals from interfering with the first optical sensor OS1 and the second optical sensor OS2 in the sensing regions 250-1 and 250-2. In some embodiments, the second well region 222 has the second conductivity type. For example, when the semiconductor substrate 200 is, for example, a P-type semiconductor substrate, the second well region 222 is, for example, an N-type well region. In some embodiments, the doping concentration of the second well region 222 is between about 1E17 atoms/cm² and about 1E18 atoms/cm².

As shown in FIGS. 1-4, the optical sensor device 500 further includes a third well region 224. The third well region 224 is located below the isolation features 204 between the sensing regions 250-1, 250-2 and the isolation region 252 and between the sensing regions 250-1 and 250-2. Moreover, the third well region 224 is adjacent to the bottom surface 220B of the first well region 220. The third well region 224 extends from a position directly below the isolation features 204 between the sensing regions 250-1, 250-2 and the isolation region 252 and between the sensing regions 250-1 and 250-2 to portions of the sensing regions 250-1 and 250-2. In the cross-sectional views of FIGS. 2 to 4, the third well region 224 in the sensing regions 250-1 and 250-2 may have the same second extended length E2 along the direction 100 substantially parallel to the top surface 201 of the semiconductor substrate 200. In some embodiments, the first extended lengths E1-1, E1-2 and E1-3 are all longer than the second extended length E2. The conductivity type of the third well region 224 can be the same as that of the first well region 220, which can be used to increase the electrical isolation performance of the isolation region 252. In some embodiments, the third well region 224 has the first conductivity type. For example, when the semiconductor substrate 200 is, for example, a P-type semiconductor substrate, the third well region 224 is, for example, a P-type deep well region. In some embodiments, the doping concentration of the third well region 224 may be lower than that of the first well region 220. In addition, the doping concentration of the third well region 224 is between about 1E16 atoms/cm² and about 1E17 atoms/cm².

As shown in FIGS. 1-3, the optical sensor device 500 further includes first heavily doped regions 218 and second heavily doped regions 219. The first heavily doped region 218 and the second heavily doped region 219 are adjacent to the top surface 201 of the semiconductor substrate 200, for example, the first heavily doped region 218 and the second heavily doped region 219 may extend from the top surface 201 of the semiconductor substrate 200 into a portion of the semiconductor substrate 200. In some embodiments, the first heavily doped region 218 is located on the first well region 220 in the isolation region 252. The second heavily doped regions 219 are located on the third doped regions 214 in the sensing regions 250-1 and 250-2 and on the second well region 222 in the guard ring region 254. In the cross-sectional views of FIGS. 2 to 4, the first heavily doped region 218 and the second heavily doped region 219 have a fourth depth D4 along the direction 110 (i.e., the distances between a bottom surfaces (not shown) of the first heavily doped region 218 and the second heavily doped region 219 and the top surface 201 of the semiconductor substrate 200), and the fourth depth D4 may be less than the third depth D3. In some embodiments, the first heavily doped region 218 has the first conductivity type, and the second heavily doped region 219 has the second conductivity type. For example, when the semiconductor substrate 200 is a P-type semiconductor substrate, the first heavily doped region 218 is, for example, a P-type heavily doped region (P+), and the second heavily doped region 219 is, for example, an N-type heavily doped region (N+). In some embodiments, the doping concentration of the first heavily doped region 218 and the second heavily doped region 219 is between about 1E20 atoms/cm² and about 1E21 atoms/cm².

In some embodiments, the first doped region 210, the second doped region 212, the third doped region 214, the first well region 220, the second well region 222, the third well region 224, the first heavily doped region 218 and the second heavily doped region 219 may be formed by implanting dopants of the first conductivity type and the second conductivity type in the semiconductor substrate 200 using multiple ion implantation and/or diffusion processes. In some embodiments, the dopant of the first conductivity type is, for example, a P-type dopant, which may include boron (B), gallium (Ga), aluminum (Al), indium (In), boron trifluoride (BF₃⁺), or a combination thereof. In some embodiments, the dopant of the second conductivity type is, for example, an N-type dopant, which may include phosphorus (P), arsenic (As), nitrogen (N), antimony (Ti), or a combination thereof.

As shown in FIGS. 1-4, the optical sensor device 500 further includes a silicide block layer 226. The silicide block layer 226 is located in the sensing regions 250-1 and 250-2, and covers a portion of the top surface 201 of the semiconductor substrate 200, so that portions of the second heavily doped regions 219 in the sensing regions 250-1 and 250-2 are exposed. The silicide block layer 226 is used to block silicide forbidden regions, to prevent subsequence silicide to be formed thereon by the silicide process, so as to maintain the electrical performances of the silicide forbidden regions.

As shown in FIGS. 1-3, the optical sensor device 500 further includes contact plugs 230. The contact plugs 230 are located on the top surface 201 of the semiconductor substrate 200 in the sensing regions 250-1 and 250-2, the isolation region 252 and the guard ring region 254. The contact plugs 230 in the sensing regions 250-1 and 250-2 are electrically connected to the second heavily doped regions 219 not covered by the silicide block layer 226, so as to detect the current signal generated from the light incident in the sensing regions 250-1 and 250-2. The contact plug 230 in the isolation region 252 is electrically connected to the first heavily doped region 218 on the first well region 220 to facilitate the external circuits to apply voltage to the first well region 220 in the isolation region 252 according to different operating conditions. In addition, the contact plug 230 in the guard ring region 254 is electrically connected to the second heavily doped region 219 on the second well region 222 to facilitate the external circuits to apply voltage to the second well region 222 in the guard ring region 254 according to different operating conditions.

Embodiments of the disclosure provide an optical sensor device, such as an optical sensor (including an ambient light sensor (ALS) for receiving visible light and a proximity sensor (PS) for receiving infrared light) applied to smartphones, By reducing the lateral size of the N-type doped region in the optical sensor for receiving visible light, the visible light absorption area can be reduced while maintaining the visible light sensitivity. In addition, by extending the P-type well region located in the isolation region to cover portions of the sensing region and surround the N-type doped region in the optical sensor for receiving visible light, the dark current problem of the optical sensor can be improved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An optical sensor device, comprising:
a semiconductor substrate having a first conductivity type, wherein the semiconductor substrate comprises a sensing region and an isolation region surrounding the sensing region;
a first doped region located in the sensing region, wherein the first doped region has a second conductivity type;
a second doped region located in the sensing region and above the first doped region, wherein the second doped region has the second conductivity type; and
a third doped region located in the sensing region and on the second doped region, wherein the third doped region has the first conductivity type, wherein in a cross-sectional view, the first doped region has a first length, and the second doped region has a second length, wherein a first ratio of the second length to the first length is greater than 0 and less than 1.

2. The optical sensor device as claimed in claim 1, wherein the third doped region has a third length in the cross-sectional view, wherein a second ratio of the second length to the third length is greater than the first ratio and less than 1.

3. The optical sensor device as claimed in claim 1, wherein the first doped region has a first projection in a direction perpendicular to the semiconductor substrate, and the second doped region has a second projection in the direction perpendicular to the semiconductor substrate, and the second projection is located within the first projection.

4. The optical sensor device as claimed in claim 3, wherein the first projection and the second projection have different shapes.

5. The optical sensor device as claimed in claim 1, wherein the third doped region extends from a top surface of the semiconductor substrate into the semiconductor substrate, and the second doped region is adjacent to a bottom surface of the third doped region and is separated from the first doped region.

6. The optical sensor device as claimed in claim 5, wherein the third doped region, the second doped region, and a portion of the semiconductor substrate between the second doped region and the first doped region form a first optical sensor.

7. The optical sensor device as claimed in claim 5, wherein a portion of the semiconductor substrate between the second doped region and the first doped region, the first doped region and another portion of the semiconductor substrate below the first doped region form a second optical sensor.

8. The optical sensor device as claimed in claim 1, further comprising:
a first well region located in the isolation region and a portion of the sensing region, wherein the first well region has the first conductivity type, and wherein the first well region partially overlaps the first doped region.

9. The optical sensor device as claimed in claim 8, wherein the first well region does not overlap the second doped region at all.

10. The optical sensor device as claimed in claim 8, wherein a bottom surface of the first well region is located between a top surface and a bottom surface of the first doped region.

11. The optical sensor device as claimed in claim 8, wherein the semiconductor substrate includes a guard ring region surrounding the isolation region, and wherein the optical sensor device further comprises:
a second well region located in the guard ring region, wherein the second well region has the second conductivity type.

12. The optical sensor device as claimed in claim 11, further comprising:
isolation features extending from a top surface of the semiconductor substrate into the semiconductor substrate, wherein the isolation features are located between the sensing region and the isolation region and between the isolation region and the guard ring region, wherein bottom surfaces of the isolation features are located above a bottom surface of the first doped region, a bottom surface of the first well region and a bottom surface of the second well region.

13. The optical sensor device as claimed in claim 12, further comprising:
a third well region located in the isolation region and a portion of the sensing region and adjacent to the bottom surface of the first well region, wherein the third well region has the first conductivity type.

14. The optical sensor device as claimed in claim 13, wherein in the cross-sectional view, the first well region has a first extended length in the sensing region, and the third well region has a second extended length in the sensing region, wherein the first extended length is longer than the second extended length.

15. The optical sensor device as claimed in claim 8, further comprising:
a first heavily doped region located on the first well region in the isolation region, wherein the first heavily doped region has the first conductivity type; and
a second heavily doped region located on the third doped region in the sensing region, wherein the second heavily doped region has the second conductivity type.
